(19) United States
(12) Patent Application Publication
(10) Pub. No.: US 2024/0421225 A1
(43) Pub. Date: Dec. 19, 2024

(54) High-Performance LDMOS Structures

(71) Applicant: Murata Manufacturing Co., Ltd., Kyoto (JP)

(72) Inventors: Jagar Singh, Clifton Park, NY (US); Anil Kumar, San Diego, CA (US); Sinan Goktepeli, Austin, TX (US); Hiroshi Yamada, San Diego, CA (US); Akira Fujihara, San Diego, CA (US); Tsunekazu Saimei, San Diego, CA (US); Kazuhiko Shibata, San Diego, CA (US)

(21) Appl. No.: 18/335,641

(22) Filed: Jun. 15, 2023

(51) Int. Cl. H01L 29/78; H01L 29/417; H01L 29/66

(52) U.S. Cl. CPC H01L 29/7835; H01L 29/41783; H01L 29/66681; H01L 29/7824

(57) ABSTRACT

High-voltage transistors that may be fabricated in a standard low-voltage process. Embodiments include integrated circuits that combine, in a unitary structure, an LDMOS FET device that includes one or more dummy polysilicon structures (DPS's) overlying a drift region and comparable in configuration to the FET gate, and interstitial implant resistance pockets (IRP) formed within the drift region between the gate and an adjacent DPS and between each pair of adjacent DPS's. The IRPs may be augmented with floating contacts to remove heat from the drift region and provide additional shielding of the drain contact from the nearest edge of the gate. The IRPs may be biased to modulate the conductivity of the drift region. The DPS's may be biased to modulate the conductivity of the drift region, and in such a way as to protect each DPS from excessive and potentially destructive voltages.

### BACKGROUND

### (1) Technical Field

This invention relates to transistor devices, and more particularly to high-voltage transistor devices.

### (2) Background

FIG. 1 is a cross-sectional view of a prior art silicon-on-insulator (SOI) N-type enhancement mode MOSFET 100 (note that the dimensions of various elements are not to scale). The transistor comprises a source 102, a self-aligned gate structure 104, and a drain 106 formed in a silicon (Si) active layer within an area defined by isolation regions 108 such as a shallow trench isolation (STI) regions. The gate structure 104 comprises an insulator (e.g., an oxide layer) 110 and overlaying gate material 112 (e.g., N+ or P+ polysilicon, or a replacement metal gate). Offset spacers 114 along the sides of the gate structure 104 may also be formed as part of the fabrication process for making the gate structure 104.

In the illustrated example, the Si active layer is formed on a buried oxide (BOX) layer formed on top of a substrate, such as a silicon substrate. A P doped well 116 (i.e., a region doped with a P-type material, such as boron) is formed in the Si active layer. The gate structure 104 is formed above a region of the P-well 116, defining a channel between the source 102 and the drain 106 when those regions are formed. The source 102 and the drain 106 are formed within the P-well 116 adjacent the gate structure 104 by implanting or diffusing N+ material, such as phosphorus or arsenic, after formation of the gate structure 104.

Electrically conductive contacts S, G, and D are made to the source 102, the gate structure 104, and the drain 106, respectively. Other common structures (e.g., device interconnects, etc.) are omitted for clarity. The multiple steps needed for making elements and features of the MOSFET 100 structure, such as masking, doping (via implanting, diffusion, etc.), epitaxial growing, cleaving, polishing, etc., are well known in the art.

As is known in the art, P-type enhancement mode MOSFETs have a similar structure, but with different doping characteristics, as do N-type and P-type depletion mode MOSFETS. Complementary metal-oxide-semiconductor (CMOS) devices use pairs of P-type and N-type MOSFETs, which may be either enhancement mode or depletion mode structures. Enhancement mode CMOS devices have very low power consumption and have become the dominant implementation technology for modern electronic systems, particularly battery-powered electronic systems.

The MOSFET 100 may be operated as an electrical switch by applying a gate-source voltage, V_{GS}, to the gate structure 104 sufficiently positive to turn the transistor ON, thereby creating a low impedance current path between the source 102 and the drain 106 through the connecting channel. The MOSFET 100 is turned OFF by applying a V_{GS} to the gate structure 104 at a voltage less than the threshold voltage, V_{T}, of the device, thereby creating a high impedance path between the source 102 and the drain 106. In other applications, the MOSFET 100 may be operated as a variable-resistance device having an output modulated by a signal (e.g., a radio frequency signal) applied to the gate structure 104.

Many electronic products, particularly mobile computing and/or communication products (e.g., notebook computers, ultra-book computers, and tablet devices), use high voltage DC and AC power sources. Examples of DC power sources are lithium ion (Li-Ion) and nickel metal hydride (NiMH) batteries, which may have DC voltages ranging from 2-100V. Examples of AC power sources include radio frequency (RF) power amplifiers, which may output voltages in excess of the power handling capabilities of single transistors, particularly MOSFET devices.

The maximum voltage handling capability of the transistor device, as used in this disclosure, is the maximum voltage between source and drain that a transistor can withstand while remaining in a non-conducting state (i.e., no significant current flow between source and drain when the gate voltage is below the transistor's threshold voltage). More specifically, the breakdown voltage, BV_{DSS} (sometimes called V_{BDSS}) of a MOSFET is the drain-source voltage at which no more than a specified drain current may flow at a specified temperature and with zero gate-source voltage [noting that breakdown of a MOSFET may be caused by various effects, being primarily avalanche breakdown (i.e., drain-channel driven breakdown), but also including punch-through (i.e., drain-source breakdown), and drain-substrate breakdown in bulk silicon; in addition, FETs inherently include a bipolar junction transistor (BJT) comprising the source, channel and drain, which is also susceptible to breakdown under certain conditions]. Typical commercially available designs for N-type MOSFETs of the type shown in FIG. 1 that are made with 45-180 nm design rules have a DC breakdown voltage of no more than about 2-3V (noting that the DC breakdown voltage generally is no more than about 2V when design rules drop below about 130 nm). In addition, the typical maximum operating voltage of conventional technology devices such as input/output MOSFETs is about 1.8 to 3.3V for many fabrication technologies (e.g., 45-180 nm design rules) in order to avoid hot carrier injection (HCI) and drain-to-gate oxide voltage breakdown. Importantly, the operational voltage V_{DS} of such transistor devices is generally set to be less than BV_{DSS}.

One improvement to the maximum voltage handling capability of a MOSFET is the laterally-diffused metal oxide semiconductor (LDMOS) transistor, which includes an asymmetric drain connection spaced from the device gate by a laterally-diffused drain (LDD) region extended well beyond the edge of the gate. For example, FIG. 2 is a cross-sectional view of a prior art SOI N-type enhancement mode LDMOS transistor 200 (note that the dimensions of various elements are not to scale). The overall structure of the LDMOS transistor 200 is similar to the MOSFET 100 of FIG. 1 (hence most reference numbers are omitted to avoid clutter). However, the N+ doped drain 106 is spaced laterally from the gate structure 104 by an N doped region 204 capped by a silicide-block region 206. In practice, additional elements such as a gate shield (not shown) are generally required to ensure that the laterally-diffused extended drain 106 and the gate structure 104 align electrostatically. Further, LDMOS transistors typically require special processes that do not integrate well with traditional CMOS circuitry, so currently most high voltage LDMOS transistors are sold as discrete devices in power amplifier markets. An additional drawback is that the size of the device is increased by the length of the N doped region 204. Additional information about the structure of various types of LDMOS transistors may be found, for example, in U.S. Pat. No. 7,230,302 B2, issued Jun. 12, 2007, entitled “Laterally Diffused Metal Oxide Semiconductor Device and Method Forming the Same”; U.S. Pat. No. 7,638,380 B2, issued Dec. 29, 2009, entitled “Method for Manufacturing a Laterally Diffused Metal Oxide Semiconductor Device”; U.S. Pat. No. 7,829,945 B2, issued Nov. 9, 2010, entitled “Lateral Diffusion Field Effect Transistor with Asymmetric Gate Dielectric Profile”; and U.S. Patent Publication US 2012/0098063 A1, published Apr. 26, 22012, entitled “Dummy Gate for a High Voltage Transistor Device”.

Another improvement to the maximum voltage handling capability of a MOSFET is use of high angle, low offset (HALO) subsurface implants (not shown) adjacent the source 102 and/or drain 106 and extending underneath the gate structure 104. Such HALO implants are regions with increased P type material that prevent the spread of depletion at high V_{DD}. As a result, such HALO implants reduce so-called punch-through, or short channel, conduction between the source 102 and the drain 106, thus increasing breakdown voltage.

The above improvements have been reasonably effective at enabling scaling down of MOSFETs and thereby enabling modern integrated circuits to follow the well-known “Moore's Law”. However, they only increase breakdown voltages by relatively small amounts (from less than a volt up to a few volts). For example, typical commercially available designs for N-type MOSFETs having LDD regions and HALO implants and made with 65-180 nm design rules have a DC breakdown voltage (BV_{DSS}) of no more than about 3V (P-type MOSFETs, which typically do not need or use HALO implants, have only a slightly higher BV_{DSS} of about 4V). Accordingly, these design tweaks generally have not been able to create individual MOSFET devices that can withstand supply voltages V_{DS} above 5V.

To extend the operational voltage V_{DS} capability of MOSFET devices to more than 5V, typically the N doped region 204 is extended even further to add resistance to the current path from the source 102 to the drain 106. For the same current I_{d},

$$( \frac{{V}_{D S}}{R} = Id ) ,$$

where R is the resistance of the N doped region 204 or “drift”, if there is an increase in V_{DS}, then R needs to increase proportionately to compensate. However, extending the N doped region 204 to increase R further increases the size of the transistor device.

More exotic high-voltage fabrication technologies, such as SiC or GaN transistors, are expensive and do not integrate well with other technologies, such as CMOS logic.

Thus, a disadvantage of prior art high-voltage transistors is that they require relatively large IC area, specialized processing, and/or exotic materials, all of which adversely impact cost, size, and availability.

Another approach to withstanding a high supply voltage for AC or RF signals—stacking low-voltage transistors—has the drawback that large stacks of transistors are required to withstand high voltages. For example, 25-35 or more conventional series-connected MOSFETs, even with LDD and HALO features, may be required to withstand a supply voltage of 75-100V. In the case of using MOSFETs in such a stack, the areal size of the stack increases with the stack height squared, thereby further increasing the size and cost of the final product.

None of the conventional approaches provides a complete solution needed to withstand high voltages. Moreover, none of the conventional approaches provides a complete solution needed to make high-voltage transistors using standard MOSFET (and particularly CMOS) processing that can meet modern size, efficiency, and cost requirements.

Accordingly, there is a need for a transistor device that can withstand high voltage and yet be fabricated in a standard low-voltage process, such as CMOS, and more specifically SOI CMOS. Such a switching device should be small in size, efficient, and low cost. The present invention addresses this and other needs.

### SUMMARY

The invention encompasses high-voltage transistors that may be fabricated in a standard low-voltage process. Embodiments of the invention include integrated circuits that combine, in a unitary structure, an LDMOS FET device that includes one or more dummy polysilicon structures (DPS's) overlying a drift region and comparable in configuration to the FET gate, and interstitial implant resistance pockets (IRP) formed within the drift region between the gate and an adjacent DPS and between each pair of adjacent DPS's. The IRPs may be augmented with floating contacts to remove heat from the drift region and provide additional shielding of the drain contact from the nearest edge of the gate. The IRPs may be biased so as to modulate the conductivity of the drift region. The DPS's may be biased independently of the gate of the FET device to modulate the conductivity of the drift region, and in such a way as to protect each DPS from excessive and potentially destructive voltages (e.g., from excessively high electric fields).

In a first embodiment, an integrated circuit high-voltage transistor in accordance with the present invention includes, in a unitary structure, a FET transistor structure having a source, a channel adjacent the source, a gate structure overlaying the channel, and a drain spaced from the channel; an integrated, co-fabricated drift region formed between the channel and the drain; one or more DPS's formed overlaying the drift region between the gate structure and the drain, wherein a first DPS is adjacent the gate structure; and at least one IRP formed within the drift region and between the gate structure and the first DPS.

The details of one or more embodiments of the invention are set forth in the accompanying drawings and the description below. Other features, objects, and advantages of the invention will be apparent from the description and drawings, and from the claims.

### DESCRIPTION OF THE DRAWINGS

FIG. 1 is a cross-sectional view of a prior art silicon-on-insulator (SOI) N-type enhancement mode MOSFET (note that the dimensions of various elements are not to scale).

FIG. 2 is a cross-sectional view of a prior art SOI N-type enhancement mode LDMOS transistor (note that the dimensions of various elements are not to scale).

FIG. 3A is a cross-sectional view of a first embodiment of a high-voltage LDMOS device in accordance with the present invention.

FIG. 3B is an enlarged portion of FIG. 3A, focused on the drift region and surrounding structures.

FIG. 3C is an enlarged portion of FIG. 3A, focused on current flow through the drift region.

FIG. 3D is an enlarged portion of FIG. 3A, focused on a first method of implantation of IRP's within the drift region.

FIG. 3E is an enlarged portion of FIG. 3A, focused on a second method of implantation of IRP's within the drift region.

FIG. 4 is a cross-sectional view of a second embodiment of a high-voltage LDMOS device in accordance with the present invention.

FIG. 5 is a cross-sectional view of a third embodiment of a high-voltage LDMOS device in accordance with the present invention.

FIG. 6 is a cross-sectional view of a fourth embodiment of a high-voltage LDMOS device in accordance with the present invention.

FIG. 7 is a cross-sectional view of a fifth embodiment of a high-voltage LDMOS device in accordance with the present invention.

FIG. 8 is a process flow chart showing one method of fabricating a high-voltage LDMOS device in accordance with the present invention.

Like reference numbers and designations in the various drawings indicate like elements.

### DETAILED DESCRIPTION

The invention encompasses high-voltage transistors that may be fabricated in a standard low-voltage process. Embodiments of the invention include integrated circuits that combine, in a unitary structure, an LDMOS FET device that includes one or more dummy polysilicon structures (DPS's) overlying a drift region and comparable in configuration to the FET gate, and interstitial implant resistance pockets (IRP) formed within the drift region between the gate and an adjacent DPS and between each pair of adjacent DPS's. The IRPs may be augmented with floating contacts to remove heat from the drift region and provide additional shielding of the drain from the nearest edge of the gate. The IRPs may be biased so as to modulate the conductivity of the drift region. The DPS's may be biased independently of the gate of the FET device to modulate the conductivity of the drift region, and in such a way as to protect each DPS from excessive and potentially destructive voltages (e.g., from excessively high electric fields).

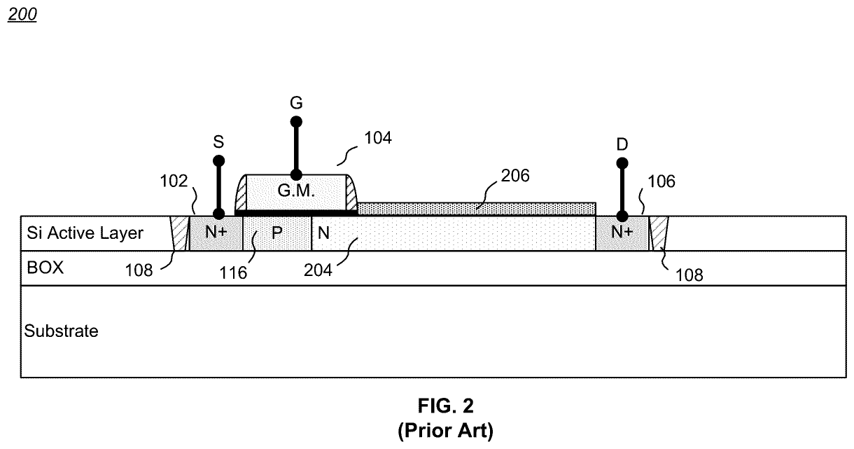

As noted above, the resistance R of the drift region of an LDMOS device must increase proportionately with an increase in V_{DS} to maintain the same current I_{D}. The present inventers have recognized that typically, the drift region resistance R equals

$$R s h \times \frac{L}{W * t} ,$$

where Rsh is the sheet resistance of the Si active layer film, L is the length (horizontally across the page for FIG. 2) of the drift region, W is the width of the transistor (into the page of FIG. 2), and t is the thickness (vertically with respect to the page for FIG. 2) of the film Si active layer, which is the thickness of the N doped region 204. Conventional LDMOS devices extend the length L of the drift region to increase the resistance R, but at the cost of increased size of the device. The present invention takes a different approach to varying the resistance R of the drift region of an LDMOS devices that enables a decrease in the size of the device and/or increases the capability of handling a large V_{DS} voltage (in excess of 5V).

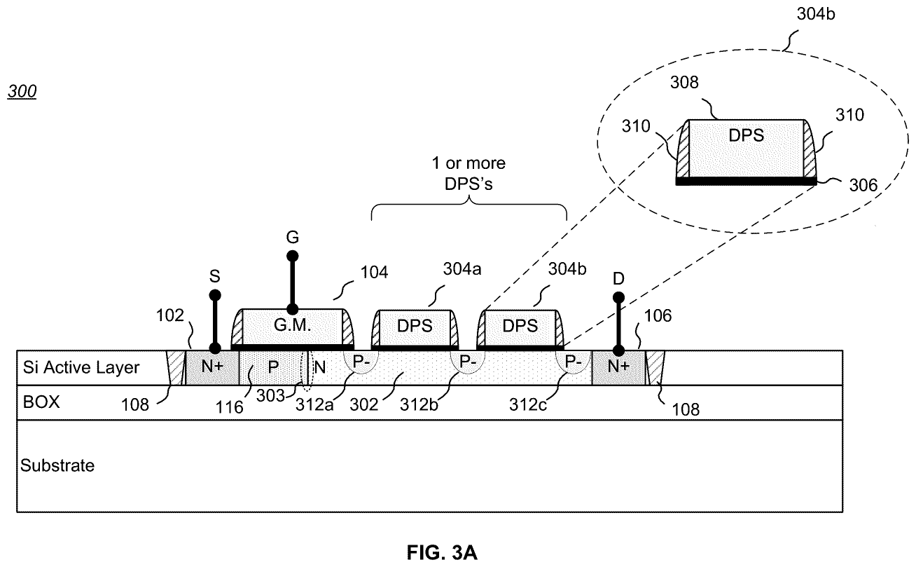

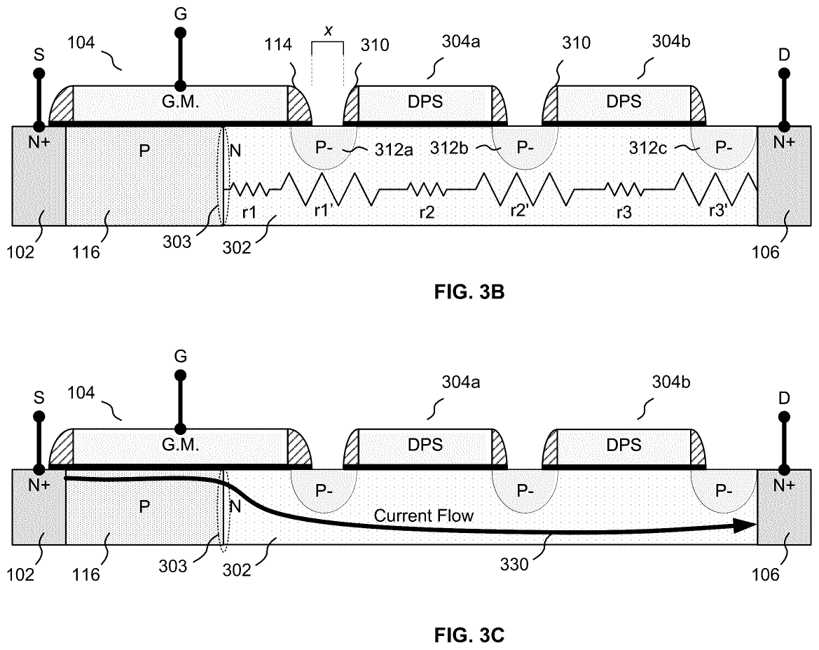

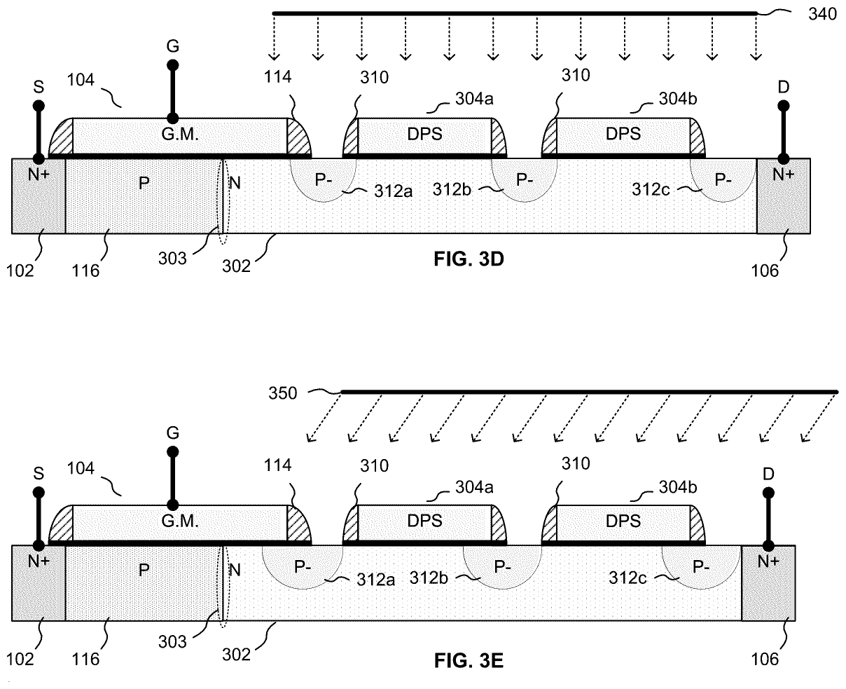

FIG. 3A is a cross-sectional view of a first embodiment of a high-voltage LDMOS device 300 in accordance with the present invention. The transistor device comprises a source 102, a self-aligned gate structure 104, and a drain 106 formed in a silicon (Si) active layer within an area defined by isolation regions 108 such as a shallow trench isolation (STI) regions. The N+ doped drain 106 is spaced from the gate structure 104 by an N doped drift region 302. A dotted oval 303 indicates the interface between the N doped drift region 302 and the P doped well 116.

In the illustrated example, the gate structure 104 has a conventional structure comprising an insulator (e.g., a Si oxide layer), overlaying gate material (e.g., N+ or P+ polysilicon, or a replacement metal gate), and offset spacers (e.g., of Si oxide) along the sides of the gate structure 104.

In the illustrated example, the Si active layer is formed on a BOX layer formed on top of a substrate. The substrate may be, for example, a high resistivity substrate, but low resistivity substrates commonly used for power FETs may also be used. Examples of high resistivity substrates include silicon-on-insulator (SOI) and silicon-on-sapphire (SOS). When SOS substrates are used, a BOX layer may or may not be present; for avoidance of doubt, embodiments of the present invention do not require the presence of a BOX layer. A similar process may be used for bulk silicon LDMOS FETs, but, as one of ordinary skill in the art would appreciated, additional doped wells may be required that insure a high breakdown voltage to the substrate (see, e.g., the triple-well example described below).

A P doped well 116 (i.e., a region doped with a P-type material, such as boron) is formed in the Si active layer. The gate structure 104 is formed above a region of the P-well 116, thereby defining a channel between the source 102 and the N doped drift region 302 when those regions are formed. The source 102 and the drain 106 are formed within the P-well 116 by implanting or diffusing N+ material, such as phosphorus or arsenic, after formation of the gate structure 104. Electrically conductive contacts S. G. D are made to the source 102, the gate structure 104, and the drain 106, respectively.

The drift region 302 may be made in a conventional manner, with a doping of N-type material up to about 5 orders of magnitude less than the doping of N-type material for the source 102 and drain 106 implants. For P-type LDMOS FETs, the polarities of the dopants and types for the various regions and wells would be reversed. Doping may be done by any conventional process, such as diffusion and/or ion implantation, to intentionally introduce impurities into a semiconductor for the purpose of modulating the electrical properties of the semiconductor. In some embodiments, the drift region 302 will encroach underneath the gate structure 104 and convert some of the underlying P-well 116 to N-type material.

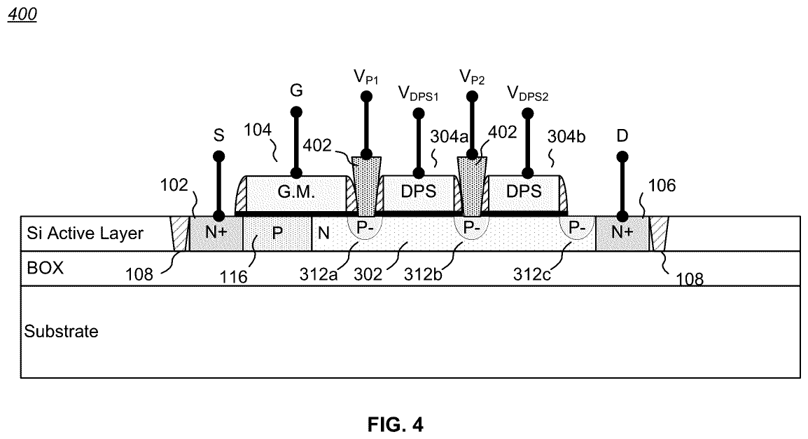

One or more dummy polysilicon structures (DPS) 304x are formed overlaying the drift region 302; in the illustrated example, two instances of the DPS 304x are shown-DPS 304a and DPS 304b. Each DPS 304x comprises an insulator 306 (e.g., an oxide layer), overlaying “dummy” gate material 308 (e.g., polysilicon), and offset spacers 310 along the sides the gate, as shown in the enlarged image of DPS 304b within the dashed oval. Thus, each DPSx 304 has a structure similar to the gate structure 104, but not necessarily including an electrically conductive contact or doping. Preferably, the DPS's 304x are made at the same time as the gate structure 104 using the same processing steps and masks; accordingly, no extra masks may be necessary. However, in many embodiments (e.g., the embodiment of FIG. 3A) it is generally beneficial to leave the overlaying gate material 308 of the DPS's 304x as an undoped material (e.g., undoped polysilicon) to provide robust drain-to-gate RF isolation. In other embodiments where electrical contacts are made to the DSP's 304x in order to modulate the channel resistance (see FIG. 4 below for an example), the overlaying gate material 308 of the DPS's 304x generally would be a doped material.

As an additional step, the LDMOS device 300 undergoes an implant step in which interstitial implant resistance pockets (IRP) 312x of P material (e.g., boron or indium in a suitable concentration, which may range from P− to P+) are formed within the N-type drift region 302 between the gate structure 104 and an adjacent DPS 304x and between each pair of adjacent DPS's 304x. In the example shown in FIG. 3A, IRP 312a is formed between the gate structure 104 and adjacent DPS 304a, and IRP 312b is formed between the pair of adjacent DPS's 304a, 304b. In some embodiments, the drain 106 may be spaced from the adjacent DPS (in this case, DPS 304b) and an optional additional IRP 312c may be formed between the adjacent DPS 304b and the drain 106. The added IRP 312c P region near the drain 106 helps to remove minority carriers effectively generated from heat or impact-ionization or similar processes. Accordingly, with an LDMOS device 300 having a single DPS 312x (e.g., DPS 312a), there is at least one IRP 312a formed within the drift region 302.

The embodiment illustrated in FIG. 3A may be fabricated using the same technology and materials as for enhancement mode N-type MOSFETs. Other common structures (e.g., device interconnects, silicide caps over the source 102, gate structure 104, and drain 106, etc.) are omitted from FIG. 3A for clarity. Other embodiments may be fabricated using the same technology and materials as for enhancement mode P-type MOSFETs, and yet other embodiments may be fabricated as depletion mode N-type MOSFETs or P-type MOSFETs. In some embodiments, no additional masks are required.

FIG. 3B is an enlarged portion of FIG. 3A, focused on the drift region 302 and surrounding structures. Superimposed on the drift region 302 is a schematic representation of the resistance across the drift region 302 after the formation of the IRP's 312x. Regions of the drift region 302 not underneath the IRP's 312x are represented as having a corresponding resistance r, while regions of the drift region 302 underneath the IRP's 312x are represented as having a corresponding resistance r′, where the resistances r′ underneath the IRP's 312x are greater than the resistances r not underneath the IRP's 312x. Accordingly, the total resistance across the drift region 302 is R=r1+r1′+r2+r2′+r3+r3′ . . . . Due to the increased resistances r′ underneath the IRP's 312x, two factors may be traded off against each other: increasing the operational voltage V_{DS} at the same device size compared to a conventional LDMOS, versus reducing the distance from the gate structure 104 to the drain 106 compared to a conventional LDMOS. For example, for the same value of R for the total resistance across the drift region 302 as a conventional LDMOS, the gate-drain distance may be reduced by 25% or more, resulting in a smaller IC footprint.

FIG. 3C is an enlarged portion of FIG. 3A, focused on current flow through the drift region 302. Due to the presence of the IRP's 312x, current flow 330 from the source 102 to the drain 106 is forced from near the top of the channel beneath the gate structure 104 to closer to the bottom of the drift region 302. In essence, the current flow path is “pinched” beneath the IRP's 312.x, thus effectively narrowing the thickness t of the film Si active layer and hence increasing resistance in those regions. In addition, moving carriers away from the top surface of the film Si active layer reduces hot carrier injection (HCI). HCI refers to a carrier being injected from the conducting channel in the silicon substrate to the gate dielectric, which adversely affects the performance and reliability of the device.

In general, the width (across the page) of the IRP's 312x may be determined by the spacing x between adjacent spacers (e.g., gate spacer 114 and DPS 304a spacer 310). Wider IRP's 312x exhibit greater resistance within the drift region 302 than narrow IRP's 312x. The IRP's 312.x will be narrowest when the gate spacer 114 and DPS 304x spacers 310 are touching adjacent spacers (the P-dopant may penetrate the spacer material). Accordingly, the spacing between the gate structure 104 and DPS's 304x may be used to vary the resistance across the drift region 302. Note that when the spacer 114 and DPS 304x spacers 310 are touching, no silicide layer need be formed over the IRP's 312.x.

Another factor that may be used to vary the resistance across the drift region 302 is the number of DPS's 304x. Adding DPS's 304x results in an increase in the number of IRP's 312x.

FIG. 3D is an enlarged portion of FIG. 3A, focused on a first method of implantation of IRP's 312x within the drift region 302. An implantation source 340 provides a flow of dopant material essential perpendicular to the plane of the drift region 302. Depending on the duration of implantation and the dopant type, the IRP's 312x may diffuse somewhat underneath the spacers 114, 310 of the gate structure 104 and DPS's 304.x.

FIG. 3E is an enlarged portion of FIG. 3A, focused on a second method of implantation of IRP's 312x within the drift region 302. An implantation source 350 provides a flow of dopant material at an angle (e.g., 30°) with respect to the plane of the drift region 302. Depending on the angle and duration of implantation and the dopant type, the IRP's 312x may diffuse underneath the spacers 114, 310 of the gate structure 104 and DPS's 304x on one side of such structures to a greater degree than on the other side. The result is offset IRP's 312x, as illustrated.

FIG. 4 is a cross-sectional view of a second embodiment of a high-voltage LDMOS device 400 in accordance with the present invention. Similar in structure to the high-voltage LDMOS device 300 of FIG. 3A, the illustrated voltage LDMOS device 400 includes three optional structures that may be used individually or in any combination.

A first optional structure comprises contacts 402 over and in at least thermal contact with the IRP's 312x. The contacts 402 may be formed of, for example, tungsten, so as to remove the heat from the drift region 302 and provide additional shielding of the drain 106 and drain contact D from the nearest edge of the gate structure 104. In some embodiments, the contacts 402 may be floating (not connected to a bias voltage). In some embodiments, the contacts 402 may be connected to a bias voltage (e.g., V_{P1}, V_{P2} . . . . V_{Pn}), as described further below.

A second optional structure comprises electrical terminals V_{DPSn} in electrical contact with corresponding DPS's 304x, either directly or through a salicide cap; a salicide cap (not shown) is formed by a self-aligned process that deposits a silicide on silicon (i.e., “salicide”=“self-aligned silicide”). Depending on the voltage applied to the electrical terminals V_{DPSn}, depletion regions may be selectively generated or not generated under the DPS's 304x. Accordingly, the DPS's 304x may be used to control the resistance of the drift region 302 through generation or removal of such depletion regions. The DPS's 304x may be biased independently of the gate structure 104. The drift region 302 may be doped at different levels to allow different types of electric field control, as described below.

In the illustrated example, the drift region 302 and DPS's 304x form an N-type depletion structure that is normally ON (i.e., conductive) when the bias voltage applied to the DPS's 304x through the electrical terminals V_{DPSn} is more positive than the threshold voltage for the drift region 302. Since the drift region 302 is normally ON, when gate structure 104 of the LDMOS device 400 is biased ON (i.e., switched to a conductive state), current may flow from the source S and pass through the drift region 302 into the drain D. In the ON state of the LDMOS device, the bias voltage for the DPS's 304x may be made even more positive to further reduce the resistance of the drift region 302, thereby reducing the ON resistance of the LDMOS device 400.

To switch the LDMOS device 400 to the OFF state, the gate structure 104 is biased OFF by applying a V_{GS} voltage less than the threshold voltage, V_{T}, of the LDMOS device 400, thereby creating a high impedance path within the channel beneath the gate structure 104. By itself, the channel is only able to withstand about 3-5V before breakdown or punch-through occurs. However, concurrently, the DPS's 304x for the drift region 302 are also biased to an OFF state by applying a bias voltage through the electrical terminals V_{DPSn} that is more negative than the threshold voltage for the drift region 302, thereby at least partially depleting the drift region 302 and thus increasing the resistance of the drift region 302 to withstand an applied high voltage. Further, the DPS's 304x may be biased sufficiently negative with respect to the threshold voltage for the drift region 302 to fully deplete the drift region 302, such that the depletion region under each DPS 304x reaches the BOX layer and pinches off all current through the drift region 302, thus further enhancing voltage drop across the drift region 302.

Note that the bias voltages applied to achieve an OFF state would not necessarily be the same for all DPS's 304x. The specific bias voltage level for each DPS 304x depends on the materials and geometry of the DPS 304x, the number of DPS's 304x, and the voltage applied to the drain 106, and accordingly is device and circuit dependent. Further, dynamic control of the drift region 302 as a function of the bias voltage applied to each DPS 304x may be applied to allow electrical fine tuning to accommodate or counteract unit-to-unit performance variations due to individual doping variations that may occur in fabricating LDMOS devices.

It should be appreciated that the OFF state and/or the ON state resistivity of the drift region 302 is affected by the doping level applied to that region; accordingly, the conductivity of the drift region 302 may be partially or fully depleted or partially or fully enhanced in the absence of biasing the DPS's 304x. For example, the drift region 302 may be doped at a level that permits only partial depletion by the DPS's 304x rather than full depletion; however, differential doping may require an extra mask. As another example, if the drift region 302 is partially or fully enhanced, a sufficiently large opposite back-side voltage may be applied to the backside of the device to invert the drift region 302, thereby reducing the ON resistance of that region.

Each DPS 304x, in conjunction with the drift region 302, provides some resistance to the voltage imposed at the drain 106. When biased in the OFF state, the DPS 304x closest to the drain 106 (e.g., DPS 304b) drops the voltage applied to the next DPS 304x (e.g., DPS 304a) along the drift region 302 by a particular amount, determined by the materials and geometry of the DPS 304x and the bias voltage applied to the DPS 304x. That next DPS 304x, and each subsequent DPS 304x, similarly drops the voltage to the next DPS 304x in line until the gate structure 104 is reached. The number of DPS's 304x may be set such that the voltage presented at the gate structure 104 is less than the breakdown voltage of the LDMOS device 400. Further information on biasing DPS-like structures may be found in U.S. Pat. No. 10,319,854, issued Jun. 11, 2019, entitled “High Voltage Switching Device”, assigned to the assignee of the present invention, the contents of which are hereby incorporated by reference.

A third optional structure comprises electrical terminal VP in electrical contact with corresponding IRP's 312x, either directly or through a salicide cap or contact 402. Depending on the voltage applied to the electrical terminals V_{Pn}, depletion under the IRP's 312.x may be increased or decreased in size by application of a suitable bias voltage when the LDMOS device 400 is in the OFF state. For example, application of a negative bias voltage to an IRP 312.x will enlarge the underlying depletion region, while application of a positive bias voltage to an IRP 312x will reduce the underlying depletion region. Accordingly, the IRP's 312x may be used to vary the resistance of the drift region 302 through expansion or contraction of such depletion regions. Such a voltage variable resistance may be particularly useful to protect the LDMOS device 700 and connected circuitry against electrostatic discharge (ESD) events in some modes of operation. The IRP's 312x may be biased independently of the gate structure 104 and/or the DPS's 304x.

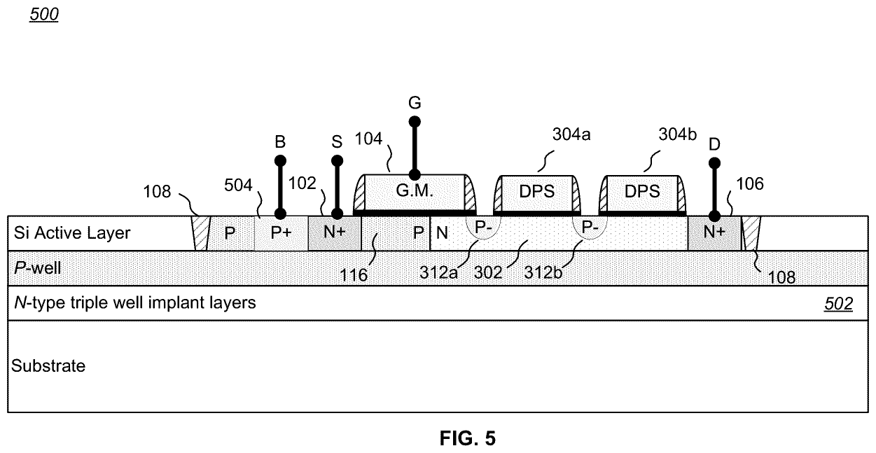

FIG. 5 is a cross-sectional view of a third embodiment of a high-voltage LDMOS device 500 in accordance with the present invention. Similar in structure to the high-voltage LDMOS device 300 of FIG. 3A, the illustrated voltage LDMOS device 500 is fabricated on a substrate that lacks a BOX layer (e.g., bulk silicon), but instead includes an N-type multiple-layer triple-well implant layer 502 on which the Si active layer and remaining structures of the LDMOS device 500 are formed. In such a structure, the P doped well 116 of the transistor overlays the deeper N-type triple-well implant layer 502. With suitable biasing, the triple-well implant layer 502 provides DC isolation similar to the isolation provided by the BOX layer in an SOI wafer.

In the illustrated example, a P+ body contact 504 is formed within the P doped well 116 to provide a connection path to the P doped well 116 of the voltage LDMOS device 500. An electrically conductive contact B is made to the body contact 504. The three optional structures shown in FIG. 4 may be included individually or in any combination.

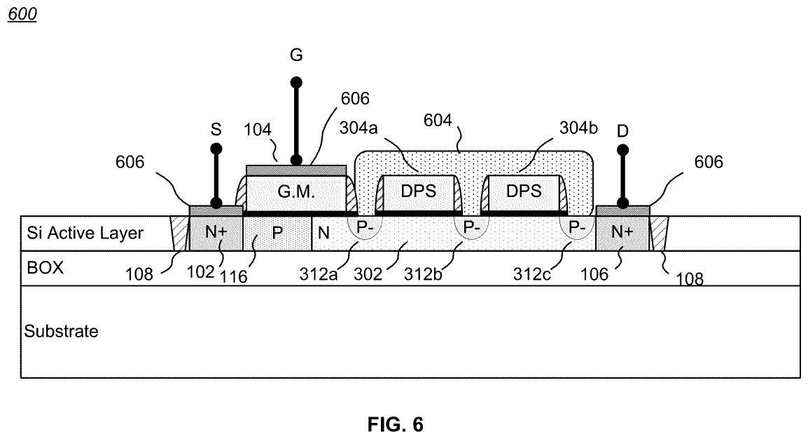

FIG. 6 is a cross-sectional view of a fourth embodiment of a high-voltage LDMOS device 600 in accordance with the present invention. Similar in structure to the high-voltage LDMOS device 400 of FIG. 4, the illustrated voltage LDMOS device 600 may be fabricated on a substrate that includes a BOX layer 602 (in alternative embodiments, triple-well implant layers may be used, adapting other structures as needed as shown in FIG. 5). A salicide block (SAB) layer 604 is formed over the IRP's 312x and DPS's 304x to prevent subsequent formation of silicide on those structures, while salicide caps 606 are formed over the source 102, the gate structure 104, and the drain 106 (and over a body contact if used). When the “dummy” gate material 308 of a DPS 304x is polysilicon, blocking salicide formation on the “dummy” gate material 308 increases the sheet resistance of the polysilicon. The SAB layer 604 may be made of, for example, silicon oxide or silicon nitride, and may be removed at a later stage of IC fabrication. Preferably the “dummy” gate material 308 of the DPS's 304x is undoped. This configuration provides better isolation between the drain 106 and gate structure 104 and between the drain 106 and source 102 at high RF frequencies (e.g., in excess of 1 GHZ). In a variant embodiment, thermally-conductive contacts 402 (see FIG. 4) may be formed over, and in at least thermal contact with, the IRP's 312x before formation of the SAB layer 604.

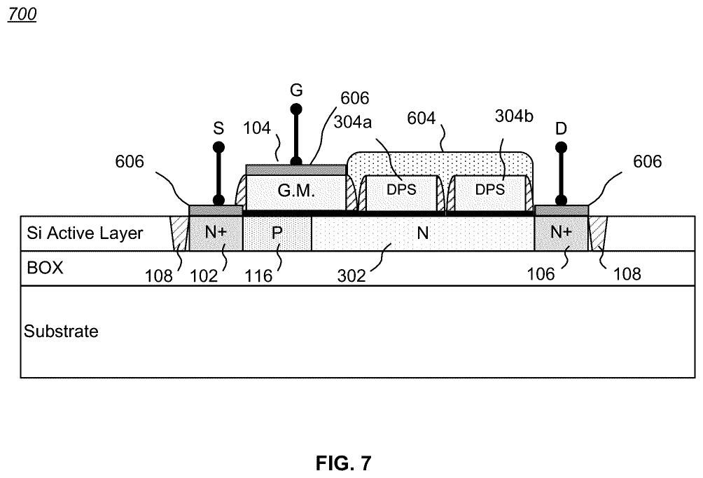

FIG. 7 is a cross-sectional view of a fifth embodiment of a high-voltage LDMOS device 700 in accordance with the present invention. Similar in many aspects to the high-voltage LDMOS device 600 of FIG. 6, the LDMOS device 700 is shown formed on a substrate supporting a BOX layer (but the LDMOS device 700 may be formed on triple-well implant layers). The overlaying “dummy” gate material 308 of the DPS's 304x is preferably undoped polysilicon. While the illustrated DPS's 304x are shown abutting each other and the gate structure 104, the DPS's 304x may be spaced apart as shown in FIG. 6. As in FIG. 6, the LDMOS device 700 includes an SAB layer 604 formed over the DPS's 304x and salicide caps 606 are formed over the source 102, the gate structure 104, and the drain 106 (and over a body contact if used). However, no IRP's 312x need be formed in this embodiment. Due to the presence of the SAB layer 604 over the spacers of the DPS's 304x, no silicide will be formed on top of the drift region 302, and accordingly the resistance R of the drift region 302 will not be reduced compared to a design that omits the SAB layer 604.

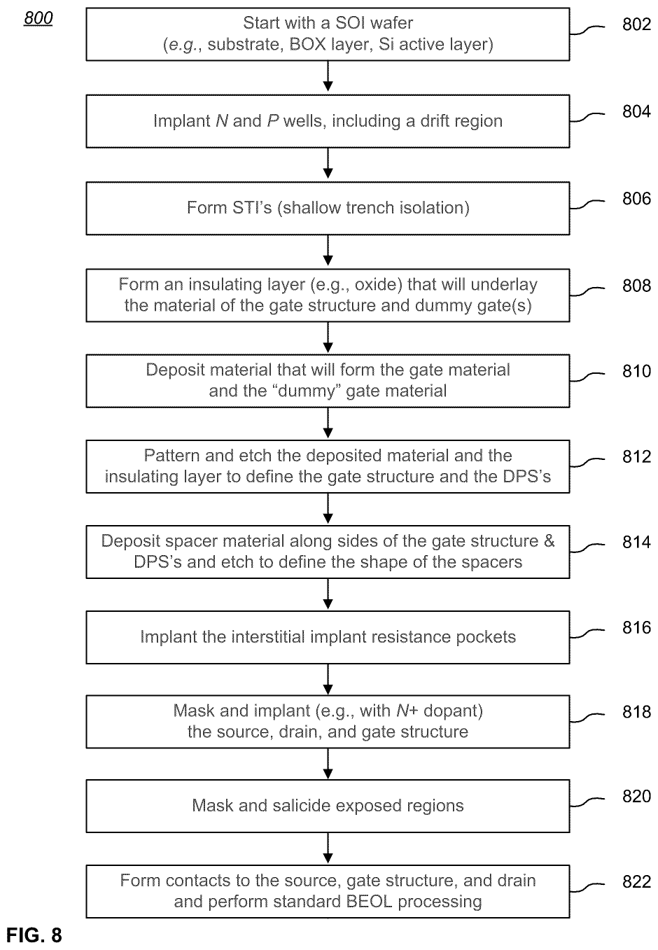

FIG. 8 is a process flow chart 800 showing one method of fabricating a high-voltage LDMOS device in accordance with the present invention. The process flow chart 800 covers the basic steps of fabricating the embodiment shown in FIG. 3A. Additional and/or alternative steps and variants of such steps may be used to fabricate the embodiments shown in FIGS. 4-7, as described above.

The example process starts with an SOI wafer (STEP 802). Such SOI wafers are commercially available, and generally comprise a silicon substrate on which a BOX layer is formed, with a silicon active layer formed on top of the BOX layer. The silicon active layer may be undoped or lightly doped. In alternative embodiments, a triple-well layer may be used instead of a BOX layer.

Next, implant desired N and P wells within the Si active layer, including a drift region (Step 804), and form STI's within the Si active layer (Step 806). Note that these two steps may be performed in the reverse order.

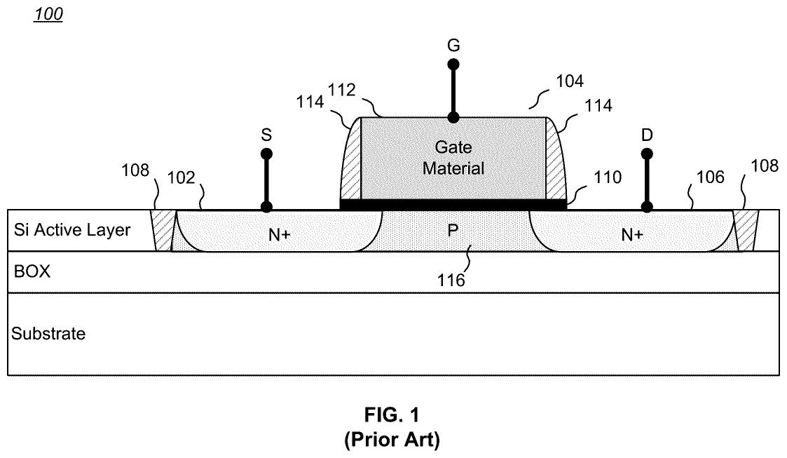

Form an insulating layer (e.g., an oxide layer) that will underlie the gate material 112 and “dummy” gate material 308; see FIGS. 1 and 3 (Step 808).

Deposit material (e.g., N+ or P+ polysilicon, or a replacement metal gate) that will form the gate material 112 and the “dummy” gate material 308 (Step 810).

Pattern and etch the deposited material and the insulating layer to define the gate structure 104 and the DPS's 304x (Step 812).

Deposit material (e.g., silicon oxide) for the spacers along the sides of the gate structure 104 and the DPS's 304x and etch (if needed) to define the shape of the spacers (Step 814).

Implant interstitial implant resistance pockets (IRPs) 312x within the drift region, such as shown in FIG. 3 (Step 816). Implantation may be made, for example, by using HALO implants of boron, difluoroboron (BF₂), or indium. The spacing between DPS's 304x may be used as a control of the depth and length of the IRPs 312x.

Mask and implant (e.g., with N+ dopant) the source, drain, and gate structure (Step 818). The DPS's 304x may be masked so as to avoid implantation of the dopant.

Mask and salicide exposed regions, e.g., as in FIG. 6 (Step 820).

Form contacts to the source 102, gate structure 104, and drain 106, and perform standard “back-end of line” (BEOL) processing (Step 822).

As one of ordinary skill in the art should appreciate, other structures (e.g., device interconnects, deep well regions, etc.) are omitted for clarity, and other or additional steps may be involved in the formation of the structures depicted in FIGS. 3A-3E and 4-7. Some common steps, such as removal of masking material after etching or implantation, are omitted. Further, some of the steps described above may be performed in an order different from that described. A person of ordinary skill in the art of FET fabrication should understand that many possible layout options exist beyond those illustrated in FIGS. 3A-3E and 4-7 without departing from the teachings of the present invention. While the illustrated example utilizes a MOSFET process with an SOI substrate, the concept may be adapted for BiCMOS and other technologies having characteristics similar to MOSFETs.

The present invention encompasses new LDMOS structures capable of handling a large operational voltage V_{DS} of 5V or more, and at the same time providing an option to either change the resistance of the current path from the source 102 to the drain 106 without increasing the IC footprint, or to reduce the IC footprint. Thus, embodiments of the present invention may provide a smaller device footprint in an LDMOS FET, while offering a variable (settable) resistance. For example, the area reduction of an N-type LDMOS FET device in accordance with the present invention compared to conventional LDMOS FET devices ranges from about 1.25× to 1.4× in modeled circuit layouts. Embodiments provide a higher value in OFF-state breakdown value and lower R_{ON} in the ON-state compared to conventional designs, which enhances overall LDMOS ON-state performance. Embodiments also exhibit lower HCI characteristics.

All of the LDMOS FET structures depicted in FIGS. 3A-3E and 4-7 may be fabricated using standard, commercially available SOI (including silicon-on-sapphire) CMOS processes without the need for additional masks for many embodiments. Both NMOSFET and PMOSFET versions of the disclosed LDMOS FETs may be combined to form CMOS devices. Therefore, LDMOS FET devices may be co-designed and co-fabricated with standard CMOS logic and circuitry. In addition to providing additional functionality, this aspect also provides the well-known low cost and high reliability advantages of CMOS technology.

Embodiments may beneficially include LDD and/or HALO implants to change or enhance the operational parameters of an LDMOS FET.

Embodiments of the inventive LDMOS FET architecture are less susceptible to damage due to ESD events than conventional MOSFETS, due to the higher value attainable value of the resistance R in a smaller device footprint. The presence of implant resistance pockets 312x helps to collect minority carriers efficiently.

As noted above, breakdown of a MOSFET may be caused by various effects, including avalanche breakdown, punch-through, and, in bulk silicon, drain-substrate breakdown. While a primary breakdown mechanism is avalanche breakdown, all of these breakdown mechanisms are mitigated by the invention by reducing the amount of voltage on the drain of a FET device by reducing the impact of voltage applied to the drain 106 on the interface 303 between the doped well 116 and the doped drift region 302.

The term “MOSFET”, as used in this disclosure, means any field effect transistor (FET) with an insulated gate and comprising a metal or metal-like, insulator, and semiconductor structure. The terms “metal” or “metal-like” include at least one electrically conductive material (such as aluminum, copper, or other metal, or highly doped polysilicon, graphene, or other electrical conductor), “insulator” includes at least one insulating material (such as silicon oxide or other dielectric material), and “semiconductor” includes at least one semiconductor material.

As should be readily apparent to one of ordinary skill in the art, various embodiments of the invention may be implemented to meet a wide variety of specifications. Unless otherwise noted above, selection of suitable component values is a matter of design choice and various embodiments of the invention may be implemented in any suitable IC technology (including but not limited to MOSFET structures). Integrated circuit embodiments may be fabricated using any suitable substrates and processes, including but not limited to standard bulk silicon (if suitable insulating wells are used to isolate the active devices from the substrate, and the well to substrate breakdown voltage exceeds the applied voltage), silicon-on-insulator (SOI), and silicon-on-sapphire (SOS). Unless otherwise noted above, the invention may be implemented in other transistor technologies having characteristics similar to MOSFETs. However, the inventive concepts described above are particularly useful with an SOI-based fabrication process (including SOS), and with fabrication processes having similar characteristics.

Voltage levels may be adjusted or voltage and/or logic signal polarities reversed depending on a particular specification and/or implementing technology (e.g., NMOS, PMOS, or CMOS, and enhancement mode or depletion mode transistor devices). Component voltage, current, and power handling capabilities may be adapted as needed, for example, by adjusting device sizes, serially “stacking” components (particularly FETs) to withstand greater voltages, and/or using multiple components in parallel to withstand greater currents. Additional circuit components may be added to enhance the capabilities of the disclosed circuits and/or to provide additional functionality without significantly altering the functionality of the disclosed circuits.

A number of embodiments of the invention have been described. It is to be understood that various modifications may be made without departing from the spirit and scope of the invention. For example, some of the steps described above may be order independent, and thus may be performed in an order different from that described. Further, some of the steps described above may be optional. Various activities described with respect to the methods identified above may be executed in repetitive, serial, or parallel fashion.

It is to be understood that the foregoing description is intended to illustrate and not to limit the scope of the invention, which is defined by the scope of the following claims, and that other embodiments are within the scope of the claims. (Note that the parenthetical labels for claim elements are for ease of referring to such elements, and do not in themselves indicate a particular required ordering or enumeration of elements; further, such labels may be reused in dependent claims as references to additional elements without being regarded as starting a conflicting labeling sequence).

1. A high voltage switching device, including an integrated circuit that combines, in a unitary structure:
(a) a transistor structure having a source, a channel adjacent the source, a gate structure over-laying the channel, and a drain spaced from the channel;
(b) an integrated, co-fabricated drift region formed between the channel and the drain;
(c) one or more dummy polysilicon structures formed overlaying the drift region between the gate structure and the drain, wherein a first dummy polysilicon structure is adjacent the gate structure; and
(d) at least one implant resistance pocket formed within the drift region and between the gate structure and the first dummy polysilicon structure.

2. The invention of claim 1, wherein the first dummy polysilicon structure is adjacent to but spaced from the gate structure.

3. The invention of claim 1, wherein there are at least two adjacent dummy polysilicon structures, further including, for each pair of adjacent dummy polysilicon structures, an implant resistance pocket formed within the drift region and between the pair of adjacent dummy polysilicon structures.

4. The invention of claim 1, wherein the source and drain are doped with a first dopant, the drift region is doped with a second dopant, and the at least one implant resistance pocket is doped with a third dopant.

5. The invention of claim 1, wherein the source and drain are N+ doped, the drift region is N doped, and each of the at least one implant resistance pocket are P doped.

6. The invention of claim 1, wherein the source and drain are P+ doped, the drift region is P doped, and each of the at least one implant resistance pocket are N doped.

7. The invention of claim 1, wherein the gate structure partially overlays the drift region.

8. The invention of claim 1, wherein the gate structure includes doped polysilicon material.

9. The invention of claim 1, wherein the one or more dummy polysilicon structures include undoped polysilicon material.

10. The invention of claim 1, wherein the at least one implant resistance pocket is formed by implantation of a dopant.

11. The invention of claim 1, wherein the at least one implant resistance pocket is formed by angled implantation of a dopant.

12. The invention of claim 1, further including at least one floating contact formed over and in thermal contact with a corresponding implant resistance pocket of the at least one implant resistance pocket.

13. The invention of claim 1, further including at least one electrical terminal in electrical contact with a corresponding dummy polysilicon structure of the one or more dummy polysilicon structures, wherein the dummy polysilicon structure having electrical terminals control the resistance of the drift region upon application of a bias voltage to the electrical terminals.

14. The invention of claim 1, further including at least one electrical terminal in electrical contact with a corresponding implant resistance pocket of the at least one implant resistance pocket, wherein the implant resistance pockets having electrical terminals control the resistance of the drift region upon application of a bias voltage to the electrical terminals.

15. The invention of claim 1, wherein the unitary structure is formed on a wafer including a substrate, a buried oxide layer formed on the substrate, and a silicon active layer formed on the buried oxide layer.

16. The invention of claim 1, wherein the unitary structure is formed on a wafer including a substrate, a triple-well implant structure formed on the substrate, and a silicon active layer formed on the triple-well implant structure.

17. A high voltage switching device, including an integrated circuit that combines, in a unitary structure:
(a) a transistor structure having a source, a channel adjacent the source, a gate structure overlaying the channel, and a drain spaced from the channel;
(b) an integrated, co-fabricated drift region formed between the channel and the drain; and
(c) one or more dummy polysilicon structures formed overlaying the drift region between the gate structure and the drain, wherein a first dummy polysilicon structure is adjacent the gate structure.

18. The invention of claim 17, wherein the first dummy polysilicon structure is adjacent to but spaced from the gate structure.

19. The invention of claim 17, wherein the gate structure partially overlays the drift region.

20. The invention of claim 17, wherein the one or more dummy polysilicon structures include undoped polysilicon material.

21. The invention of claim 17, wherein the unitary structure is formed on a wafer including a substrate, a buried oxide layer formed on the substrate, and a silicon active layer formed on the buried oxide layer.

22. The invention of claim 17, wherein the unitary structure is formed on a wafer including a substrate, a triple-well implant structure formed on the substrate, and a silicon active layer formed on the triple-well implant structure.

23.-25. (canceled)
